(19) United States
(12) Patent Application Publication
(10) Pub. No.: US 2011/0175602 A1
(43) Pub. Date: Jul. 21, 2011

(54) INDUCTORS WITH UNIFORM MAGNETIC FIELD STRENGTH IN THE NEAR-FIELD

(75) Inventors: Hua Wang, Hillsboro, OR (US); Seyed Ali Hajimiri, La Canada, CA (US)

(73) Assignee: California Institute of Technology, Pasadena, CA (US)

(21) Appl. No.: 12/978,296

(22) Filed: Dec. 23, 2010

Related U.S. Application Data
(60) Provisional application No. 61/289,925, filed on Dec. 23, 2009.

(51) Int. Cl. G01R 33/28; H01F 5/00

(52) U.S. Cl. 324/239; 336/200

(57) ABSTRACT

An integrated inductor includes a plurality of coils. Each of the plurality of coils is electromagnetically coupled together to form an inductor between a first inductor terminal and a second inductor terminal. At least one of the plurality of coils is disposed in a layer on an integrated structure and at least another of one of the plurality of coils disposed in a layer of the integrated structure. One of the plurality of coils is spaced with respect to another of the plurality of coils to cause a substantially uniform magnetic field strength across a surface of the integrated inductor. An integrated magnetic particle sensor system, an integrated inductor having a section having a different width than another section, an integrated inductor having at least one gradual transition section, and an integrated inductor having at least one floating metal structure are also described.

### CROSS-REFERENCE TO RELATED APPLICATIONS

This application claims priority to and the benefit of co-pending U.S. provisional patent application Ser. No. 61/289,925, Design of Inductors with Uniform Magnetic Field Strength in the Near-Field, filed Dec. 23, 2009. This application is also related to co-pending U.S. patent application, EFFECTIVE-INDUCTANCE-CHANGE BASED MAGNETIC PARTICLE SENSING, Ser. No. 12/399,603, filed Mar. 6, 2009, to co-pending U.S. patent application, FULLY INTEGRATED TEMPERATURE REGULATOR FOR BIOCHEMICAL APPLICATIONS, Ser. No. 12/399,320, filed Mar. 6, 2009, and to co-pending U.S. patent application, A FREQUENCY-SHIFT CMOS MAGNETIC BIOSENSOR ARRAY WITH SINGLEBEAD SENSITIVITY AND NO EXTERNAL MAGNET, Ser. No. 12/559,517, filed Sep. 15, 2009. Each of the above-identified applications is incorporated herein by reference in its entirety for all purposes.

### FIELD OF THE INVENTION

The invention relates to inductors in general and particularly to inductors which employ a structure that provides a more uniform near-field magnetic field strength.

### BACKGROUND OF THE INVENTION

Future Point-of-Care (PoC) molecular level detection will use advanced sensing platforms with hand-held portability, high-sensitivity, low-cost, and battery-level power consumption. Such sophisticated field diagnostic equipment will likely replace existing centralized lab-based diagnostics facilities. These PoC systems, once fully developed, can function as mass-deployable units to address on-site medical diagnostic applications such as home-based health care, epidemic disease control, and environmental monitoring.

Although widely used, fluorescence-based molecular detection schemes generally need bulky and expensive optical devices and experience signal decaying or quenching issues. Magnetic particle based sensing platforms have been proposed to augment or replace the optical approach. However, magnetic sensors generally need magnetic fields for external biasing and/or complicated post-processing, thus limiting their form factor and cost. Another problem is the ability to generate a polarization magnetic field that can provides a substantially uniform transducer gain.

Thus, there is a need for an inductor which can provide a more uniform near field, particularly for sensing applications.

### SUMMARY OF THE INVENTION

According to one aspect, the invention features an integrated inductor which includes a plurality of coils. Each of the plurality of coils is electromagnetically coupled together to form an inductor between a first inductor terminal and a second inductor terminal. At least one of the plurality of coils is disposed in a layer on an integrated structure and at least another of one of the plurality of coils is disposed in a layer of the integrated structure. One of the plurality of coils is spaced with respect to another of the plurality of coils to cause a substantially uniform magnetic field strength across a surface of the integrated inductor.

In one embodiment, at least one of the plurality of stacked coils is disposed in a first layer of the integrated structure and at least another one of the plurality of coils is disposed in a second layer of the integrated structure.

In another embodiment, at least two of the plurality of stacked coils have different diameters and the plurality of stacked coils creates a geometric bowl shaped inductor.

In yet another embodiment, the integrated inductor of further includes at least one floating metal structure.

In yet another embodiment, the integrated inductor further includes an interconnecting electrically coupled between the at least one of said plurality of coils at least another of one of the plurality of coils, the interconnecting trace configured to provide a gradual vertical transition to adjust the current distribution within said integrated inductor magnetic sensor device.

In yet another embodiment, the integrated inductor further includes an inner widened turn.

According to another aspect, the invention features an integrated magnetic particle sensor system which includes at least one integrated magnetic particle sensor inductor having a feature of a selected one of: a bowl-shaped inductor, a floating metal structure, and a section of a trace having a different width than another section, the integrated magnetic particle sensor inductor configured to provide a substantially homogenous near-field magnetic field at a sensing surface. The integrated magnetic particle sensor inductor is electrically coupled to an integrated capacitor and configured as an oscillator LC sensing core. The LC sensing core is configured such that a frequency of the oscillator LC sensing core is indicative of the presence of one or more magnetic particles.

In one embodiment, the integrated magnetic particle sensor is configured to detect the presence of one or more magnetic particles.

In another embodiment, the single magnetic particle is detectable at any location on of the sensing surface.

In yet another embodiment, at least one of the one or more magnetic particles is affixed to a target molecule.

In yet another embodiment, the integrated magnetic particle sensor is configured to provide a linear sensor response with respect to a number of magnetic particles.

In yet another embodiment, the integrated magnetic particle sensor system further includes one or more additional LC sensing cores to form an array of LC sensing cores, each of the LC sensing cores is selected by a multiplexer.

In yet another embodiment, the integrated magnetic particle sensor system is configured to use a Correlated Double Counting (CDC) for noise cancellation.

In yet another embodiment, at least one of the LC sensing core and the n additional LC sensing cores is configured as a reference cell, and the remaining LC sensing cores are configured as measurement cells.

In yet another embodiment, the integrated magnetic particle sensor system of claim 12, further includes m arrays of n LC sensing cores and wherein each of the m arrays is selected by a multiplexer.

In yet another embodiment, the integrated magnetic particle sensor system includes a bio-sensing system.

In yet another embodiment, the bio-sensing system is configured for use with a selected one of, genomics level (DNA/RNA) bio-sample and cellular level (bacteria) bio-sample.

According to yet another aspect, the invention features an integrated inductor which includes a plurality of coils. Each of the plurality of coils is electromagnetically coupled together to form an inductor between a first inductor terminal and a second inductor terminal. At least one of the plurality of coils is disposed in a layer on an integrated structure and at least another of one of the plurality of coils disposed in a layer of the integrated structure. At least a portion of one coil of the plurality of coils has a section having a different width than another section and configured to cause a substantially uniform magnetic field strength across a surface of the integrated inductor.

According to yet another aspect, the invention features an integrated inductor which includes a plurality of coils. Each of the plurality of coils is electrically coupled together to form an inductor between a first inductor terminal and a second inductor terminal. At least one of the plurality of coils is disposed in a layer on an integrated structure and at least another of one of the plurality of coils disposed in a layer of the integrated structure. At least one gradual transition section disposed between at least two coils of the plurality of coils is configured to cause a substantially uniform magnetic field strength across a surface of the integrated inductor.

According to yet another aspect, the invention features an integrated inductor which includes a plurality of coils. Each of the plurality of coils is electromagnetically coupled together to form an inductor between a first inductor terminal and a second inductor terminal. At least one of the plurality of coils is disposed in a layer on an integrated structure and at least another of one of the plurality of coils disposed in a layer of the integrated structure. At least one floating metal structure is disposed on or near a the layer has a substantially optimized geometry configured to cause a substantially uniform magnetic field strength across a surface of the integrated inductor.

The foregoing and other objects, aspects, features, and advantages of the invention will become more apparent from the following description and from the claims.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

FIG. 1 shows a set of exemplary process steps for a frequency-shift magnetic particle sensing scheme.

FIG. 2 shows a graph of sensor response plotted versus the number of magnetic particles for a frequency-shift magnetic particle sensing scheme, such as that of FIG. 1.

FIG. 3 shows a perspective view of a symmetric spiral inductor.

FIG. 4A shows a perspective view of one embodiment of a bowl-shaped inductor according to the invention.

FIG. 4B shows a HFSS near field simulation result for the inductor of FIG. 4A.

FIG. 5A shows a perspective view of an embodiment of a bowl-shaped inductor having a floating metal structure according to the invention.

FIG. 5B shows a HFSS near field simulation result for the inductor of FIG. 5A.

FIG. 6 shows a graph of effective inductance (L_{eff}) and effective quality factor (Q_{eff}) plotted versus frequency for an inductor with and without a floating metal structure.

FIG. 7A shows a perspective view of an exemplary Design 1 modeled inductor according to the invention.

FIG. 7B shows a top view of the Design 1 modeled inductor.

FIG. 7C shows the HFSS near field simulation result.

FIG. 8A shows a perspective view of an exemplary Design 6 modeled inductor according to the invention.

FIG. 8B shows a top view of the Design 6 modeled inductor.

FIG. 8C shows the Design 6 HFSS near field simulation result.

FIG. 9A shows a perspective view of an exemplary Design 14 modeled inductor according to the invention.

FIG. 9B shows a top view of the Design 14 modeled inductor according to the invention.

FIG. 9C shows the Design 14 HFSS near field simulation result.

FIG. 10A shows a perspective view of an exemplary Design 19 modeled inductor according to the invention.

FIG. 10B shows a top view of the Design 19 modeled inductor

FIG. 10C, FIG. 10D and FIG. 10E show the Design 19 HFSS near field simulation results.

FIG. 11 shows a graph of effective inductance and effective Q plotted versus frequency for the inductors of FIG. 7A and FIG. 10A.

FIG. 12 shows a schematic diagram an exemplary quad-core sensor cell.

FIG. 13 shows a block diagram of one exemplary sensor system architecture.

FIG. 14 shows a chip micrograph of one embodiment of a sensor system implemented according to the block diagram of FIG. 13.

FIG. 15 shows a graph of frequency counting results in the time domain for sensor system of FIG. 14.

FIG. 16 shows a graph of Frequency counting standard deviation for several different counting times T.

FIG. 17 shows a micrograph and graph illustrating an exemplary system response to a single randomly placed 4.5 nm magnetic particle.

FIG. 18 shows frequency shift plotted versus the number of beads present on the sensor surface.

### DETAILED DESCRIPTION

In several related applications, including co-pending U.S. patent application, EFFECTIVE-INDUCTANCE-CHANGE BASED MAGNETIC PARTICLE SENSING, Ser. No. 12/399,603, filed Mar. 6, 2009, co-pending U.S. patent application, FULLY INTEGRATED TEMPERATURE REGULATOR FOR BIOCHEMICAL APPLICATIONS, Ser. No. 12/399,320, filed Mar. 6, 2009, and co-pending U.S. patent application, A FREQUENCY-SHIFT CMOS MAGNETIC BIOSENSOR ARRAY WITH SINGLEBEAD SENSITIVITY AND NO EXTERNAL MAGNET, Ser. No. 12/559,517, filed Sep. 15, 2009, we described sensing components which can be used to manufacture systems that can detect from one to many magnetic particles, such as for example, microscopic magnetic particles which can be captured by molecules. Sensor systems that can detect and/or count small magnetic particles in a sample are suitable for use in a wide variety of analysis and diagnostic equipment, such as for example, medical diagnostic instruments. When some or all of such systems are integrated onto one or more substrates, these sensor systems can be used to manufacture medical diagnostic instruments, such as relatively small portable low power battery powered medical diagnostic instruments. Each of the above-identified applications is incorporated herein by reference in its entirety for all purposes.

### Introduction

We describe hereinbelow several embodiments of new inductor structures that have a substantially uniform magnetic field strength in the near-field. Such structures have a highly uniform magnetic near-field field and are particularly well suited for fabrication as integrated structures. Thus, these new types of inductors solve the problem of how to generate a polarization magnetic field that can provide a substantially uniform transducer gain. Since these inductors can be manufactured as integrated structures, they are particularly suitable for use in small portable low power biological and/or medical magnetic particle sensing systems.

Following a brief description of biosensor applications, we describe in detail the new inductor structure which provides a spatially uniform sensor gain. We then describe several embodiments of the inventive inductor that we modeled using computer simulations. Following the description of our modeling results, we describe one exemplary embodiment of an integrated magnetic particle sensor system. This exemplary implementation, which we built and tested as an integrated structure, included the inventive inductor structures. The inductors provided the “L” for the integrated on-chip LC (inductor, capacitor) resonant tank circuits of the oscillator magnetic “sensor cores”.

Sensor cores: On-chip LC resonant tank of an oscillator can be used as “sensor cores”. The magnetic field generated by the inductor polarizes the magnetic particles close to the sensor surface, resulting in an increase in total magnetic energy in the space. This leads to an effective increase in the inductance, which translates to a corresponding down-shift in the oscillation frequency. This aspect of our inventive magnetic particle sensing system has been described in more detail in the co-pending applications cited hereinabove.

### Sensor Mechanisms and Sensor Transducer Gain Modeling

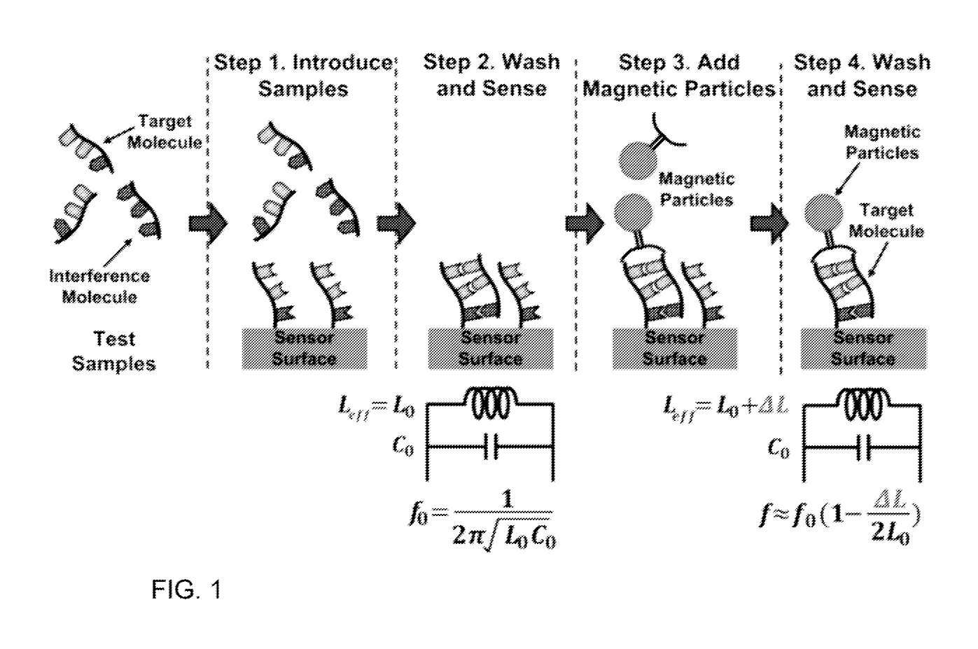

Turning now to biological diagnostic systems, some embodiments of magnetic biosensors can use sandwich-based bioassays, such as for example, an Enzyme-Linked ImmunoSorbent Assay (ELISA), where magnetic particles provide sensing tags. The method steps of one exemplary frequency-shift magnetic sensing scheme are illustrated in FIG. 1. During the detection process, pre-deposited molecular probes first capture the target molecules in the sample. Biochemically functionalized magnetic particles can then be introduced and immobilized by the captured target molecules. Then, the presence of the target molecules in a test sample disposed on a sensor surface can be directly measured (both qualitatively and quantitatively) by sensing the magnetic particles.

### Sensing Inductor Design for Spatially Uniform Sensor Gain

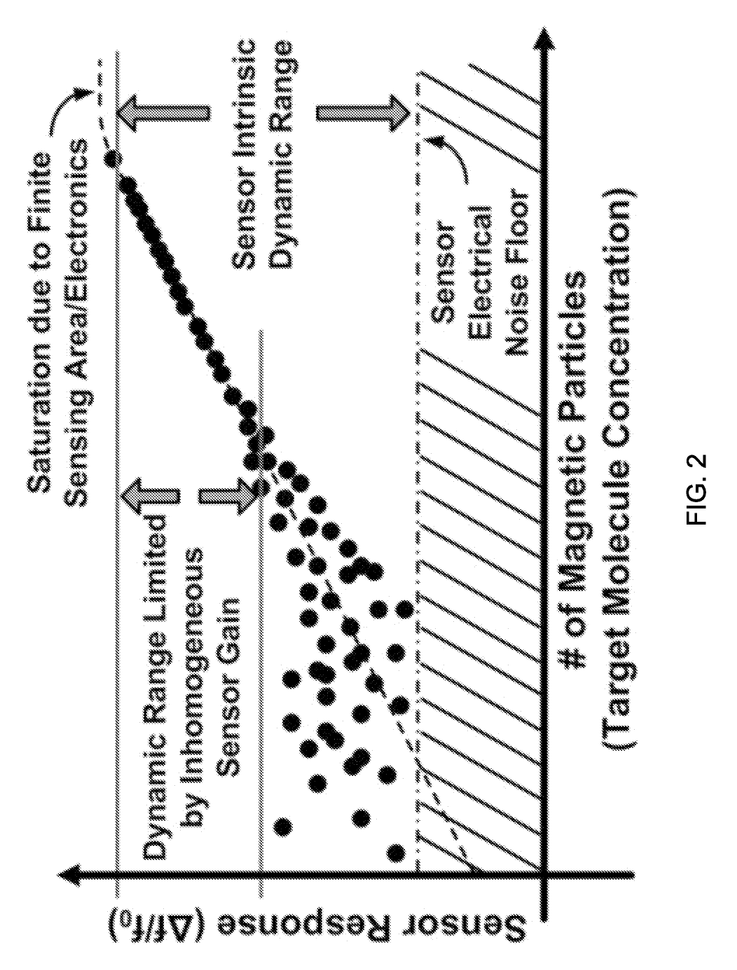

Development of magnetic particle based sensing systems has been hampered by an inability to achieve a polarization magnetic field that can provide a substantially spacially uniform transducer gain. Location-dependent transducer gain directly affects the sensor performance. For practical magnetic molecular diagnosis, the positions of the immobilized magnetic particles are distributed randomly on the sensor surface. A large number of particles can spatially “average out” this in-homogeneity. However, when detecting small particle counts (e.g. at low target molecule concentrations), non-uniform transducer gain can cause inconsistent output signals for different particle distributions. Thus, non-uniform transducer gain creates an effective noise floor. This effective noise floor can completely mask the fundamental sensor electrical noise-floor (1/f³ phase noise dependent), significantly compromising a system's dynamic range. The graph of FIG. 2 shows how dynamic range is degraded by the non-uniform sensor gain.

Inductors with Uniform Magnetic Field Strength in the Near Field

We now describe in detail a new sensing inductor design methodology and new sensing inductor structures which achieve a substantially uniform sensor transducer gain and which solves the problem of degraded dynamic range described hereinabove. According to the invention, such sensing inductors can, for example, have a bowl-shaped structure, interconnecting traces disposed to enhance near-field uniformity, and/or one or more floating metal structures, to enhance the near-field uniformity.

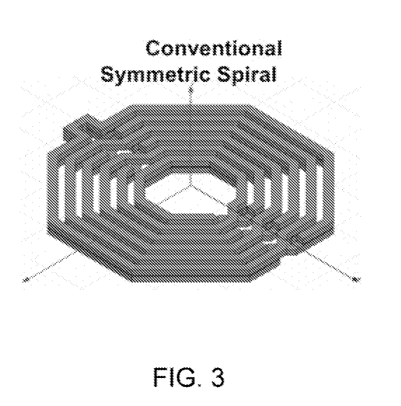

Symmetric Inductors: Symmetric inductors, such as the exemplary symmetric spiral inductor of FIG. 3, have been used for on-chip differential LC oscillators. However, a symmetric inductor typically presents a highly non-uniform magnetic field strength |B| on its surface. Measured radially from the inductor's center to its edge, the field strength first increases due to the closer distance towards the metal traces. Then |B| gradually achieves its peak value when the magnetic field addition from all the turns is maximized. The field strength decreases after this peak, because of the weaker coupling and greater distance from the traces. With this field distribution, generally only the center of a symmetric inductor presents a relatively uniform transducer gain, which significantly limits the linear sensing area.

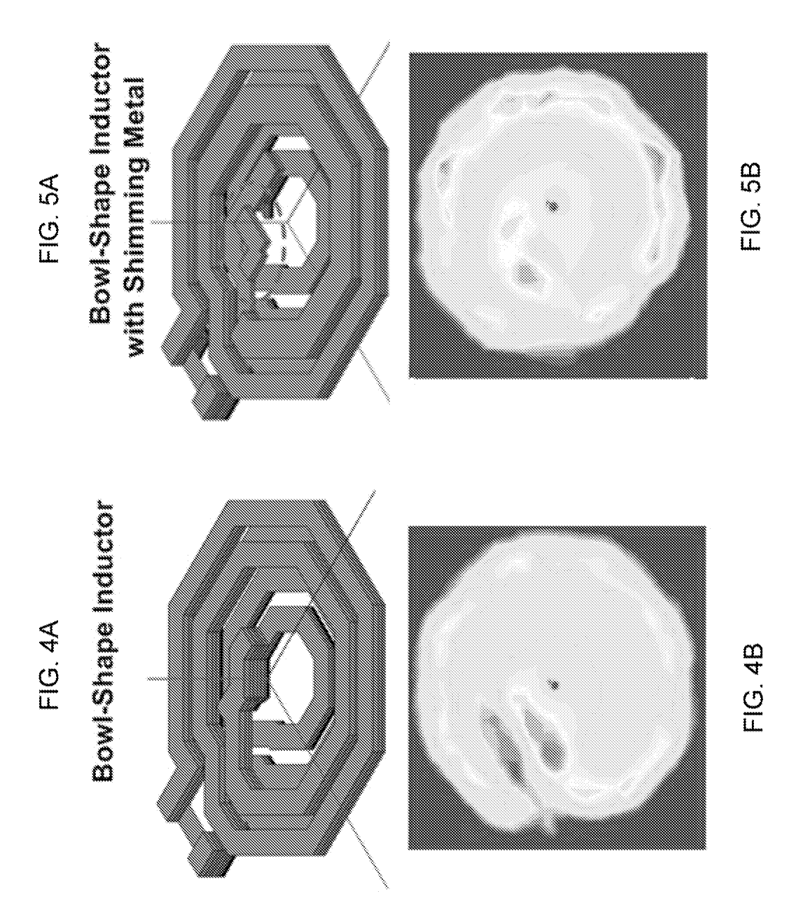

Bowl-Shape Inductors: Stacked coils, according to the invention, can be used to provide more degrees of freedom for shaping the polarization magnetic field. A dual-layer stacked inductor whose lower-level traces are deliberately spaced with respect to the upper ones to mitigate the |B| peaks and equalizes the magnetic field strength across the inductor. A significant uniformity on |B| can be observed. However, peaks and valleys of the field strength |B| exist at the connections between the two coil layers due to the current crowding effect. FIG. 4A shows a perspective view of one exemplary bowl-shaped inductor according to the invention. FIG. 4B shows a HFSS near field simulation result for the inductor of FIG. 4A.

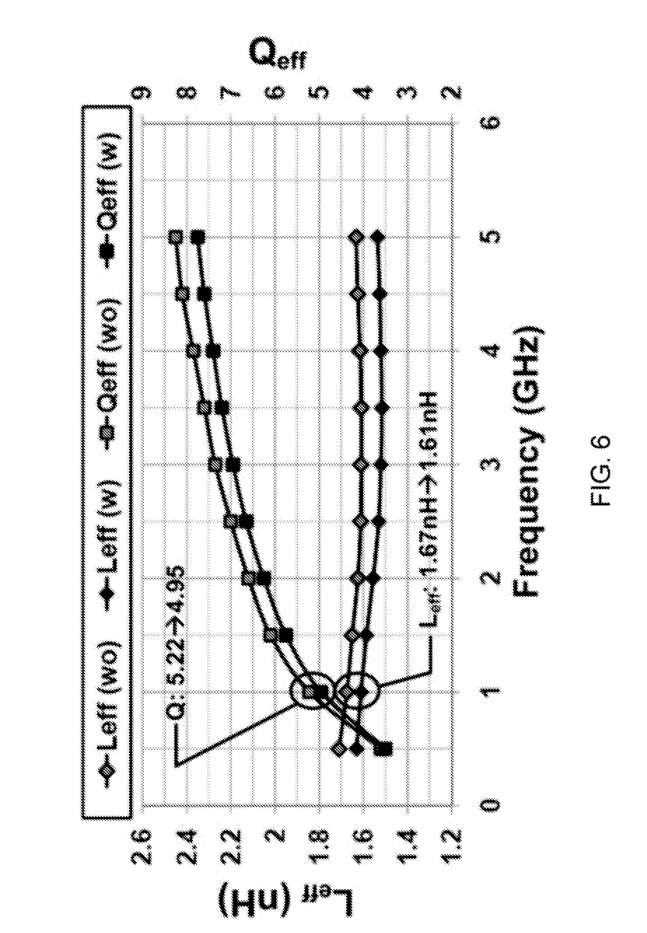

Floating Metal Structure: In other embodiments, there can be a floating metal structure. The magnetic field of the floating metal structure is induced by its eddy current and causes changes in the local total magnetic field strength and can be used to suppress spatial |B| variation. FIG. 5A shows a perspective view of one embodiment of a bowl-shaped inductor with a floating metal structure according to the invention. FIG. 5B shows a HFSS near field simulation result for the inductor of FIG. 5A.

Interconnecting traces: In order to suppress this non-uniformity, in some embodiments, one or more of the interconnecting traces can be designed to have a more gradual vertical transition between the layers to adjust the current distribution. For example, FIG. 5A (simulated in FIG. 5B) shows such a gradual transition between the metal layers (behind the floating metal structure).

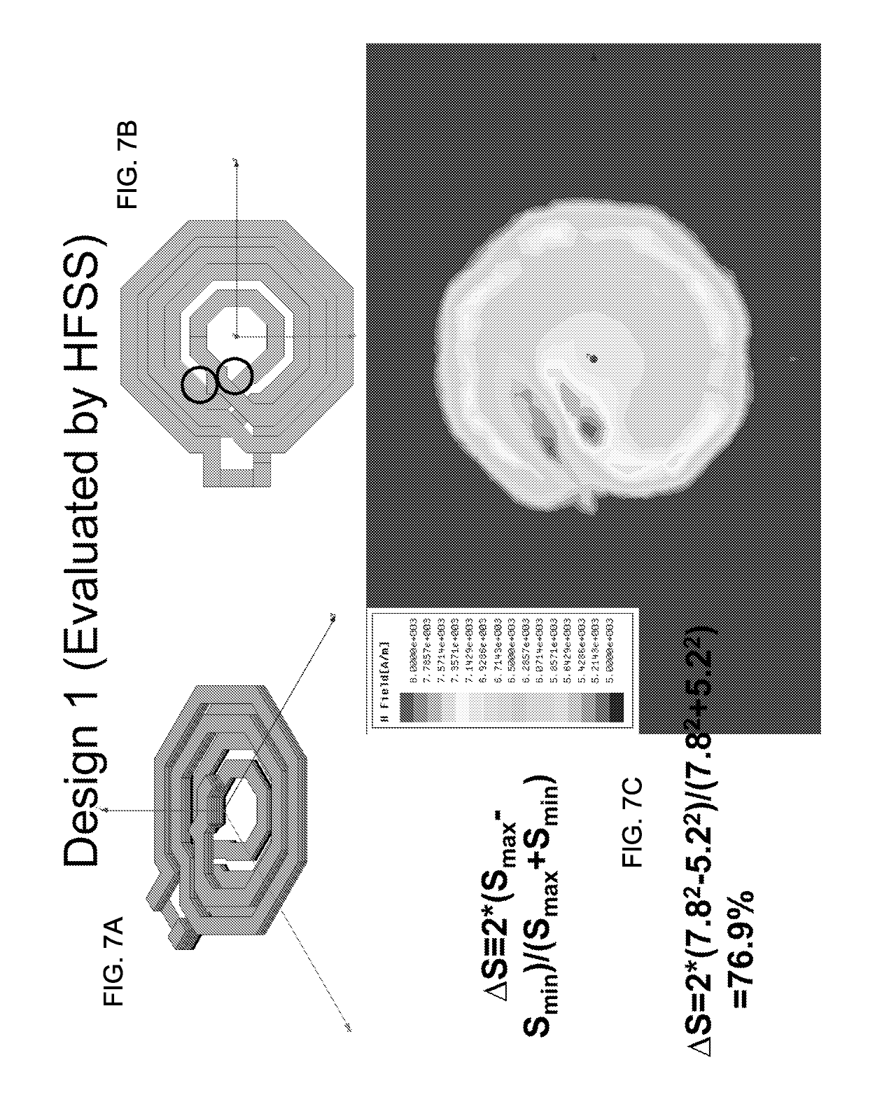

FIG. 6 shows a graph of effective inductance (L_{eff}) and effective quality factor (Q_{eff}) plotted versus frequency for an inductor without a floating metal structure and for an inductor with a floating metal structure. At a 1 GHz operating frequency, the simulated effective inductance and quality factor for the inductor show negligible changes after applying the floating metal structure. In still other embodiments, an inner turn of the upper-layer trace can be widened to further improve the transducer gain homogeneity. The embodiment of FIG. 5A (simulated in FIG. 5B) has a wider inner turn upper-layer trace.

While in some embodiments there are stacked coils on two or more layers of an integrated structure, it is understood that there could be two or more coils spaced horizontally on a single layer in place of, or in addition to coils on two or more layers. Also, while in some embodiments a section of a trace has been widened, it is understood that in other embodiments at least a portion of one coil of said plurality of coils can have a section having a different width (either narrower or wider) than another section and to cause a substantially uniform magnetic field strength across a surface of said integrated inductor.

### Modeling

We turn now to modeling. As described hereinabove, our inventive inductor structures can include a bowl-shaped inductor, metal pieces (either floating or connected to some electrical potential), additional coils (either on-chip or off-chip), and/or interconnecting traces. It is also contemplated that additional coils having any suitable impedance can be connected and/or coils can be driven and/or coupled with any suitable sources (current sources or voltages) to improve the excitation magnetic field generated by a sensing inductor to realize a spatially uniform transducer gain. We have found through both modeling and testing of prototypes that these aforementioned structures and methods (and any combination thereof) can be used to design inductors with an arbitrary B field configuration at the near field.

In the modeling examples which follow, the near-field B field amplitude as generated by each exemplary designed inductor was simulated using the electromagnetic field modeling program HFSS (available from ANSYS, Inc., Canonsburg, Pa.). |B|² is used to evaluate the B field uniformity for the near-field, and more specifically, B field uniformity is defined as: 2*(max|B|²−min|B|²)/(max|B|²−min|B|²).

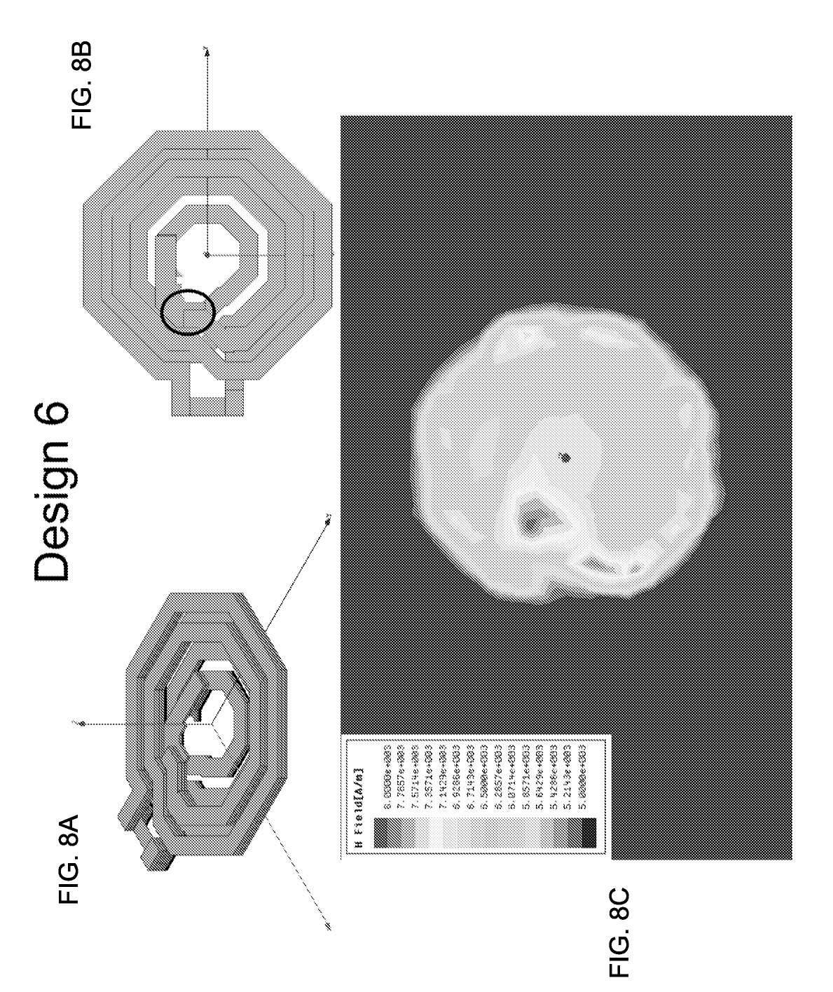

The example of FIG. 7A, FIG. 7B, and FIG. 7C illustrates one exemplary design (our “Design 1”), having bowl-shaped inductor and a floating metal structure to enhance magnetic field homogeneity. FIG. 7A shows a perspective view of the Design 1 modeled inductor, FIG. 7B shows a top view of the Design 1 modeled inductor, and FIG. 7C shows the HFSS near field simulation result.

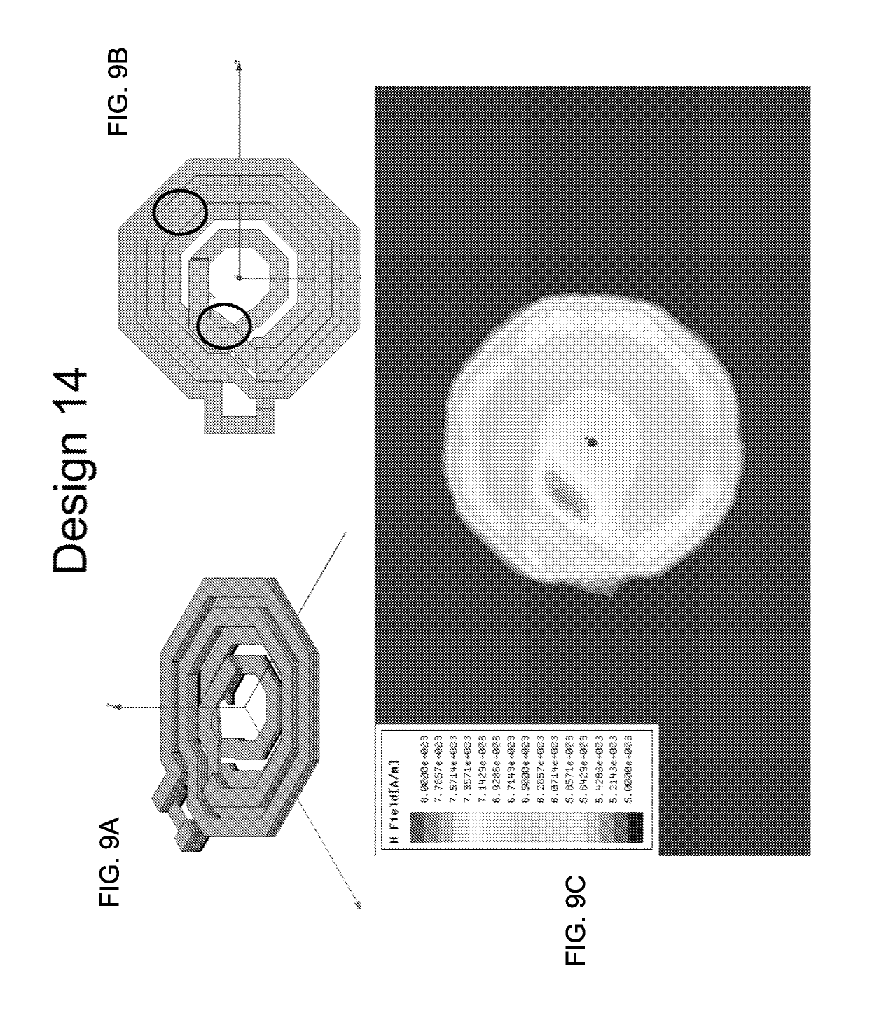

The example of FIG. 8A, FIG. 8B, and FIG. 8C illustrates another exemplary design (our “Design 6”), having bowl-shaped inductor and a floating metal structure having relatively gradual transitions for the electrical currents flowing between the upper-layer trace to the lower-layer trace which further enhances magnetic field homogeneity. FIG. 8A shows a perspective view of the Design 6 modeled inductor, FIG. 8B shows a top view of the Design 6 modeled inductor, and FIG. 8C shows the Design 6 HFSS near field simulation result.

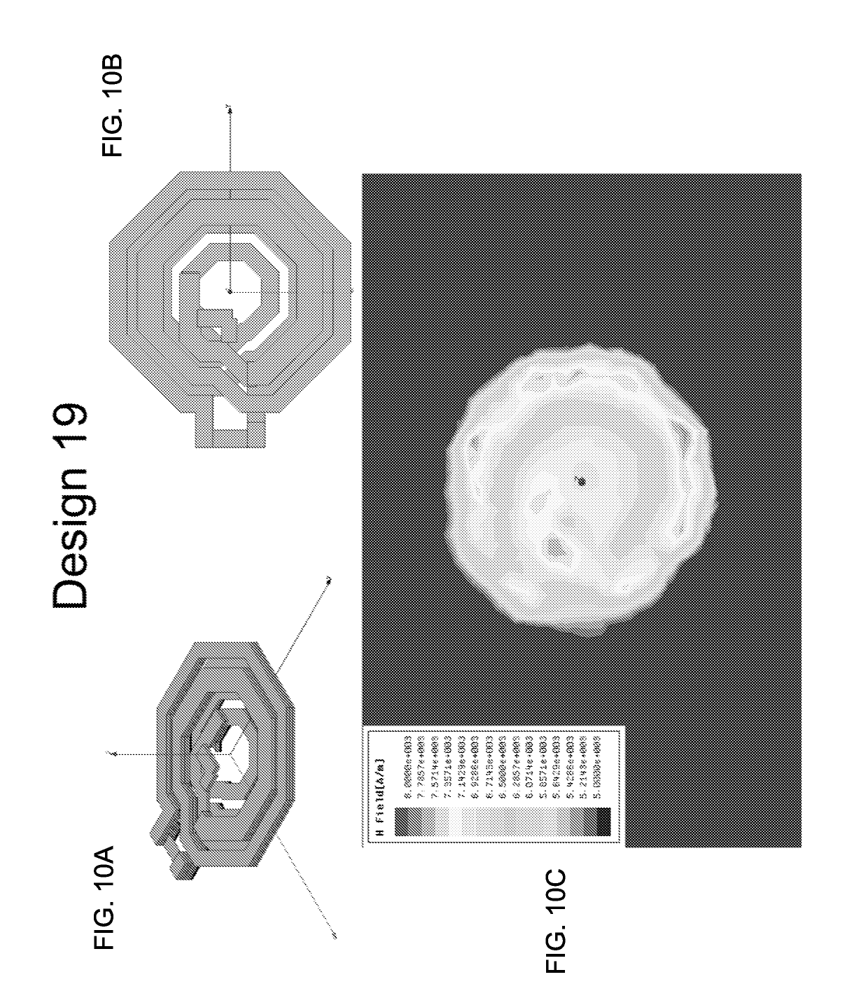

The example of FIG. 9A, FIG. 9B, and FIG. 9C illustrates yet another exemplary design (our “Design 14”), having bowl-shaped inductor and a floating metal structure a smoother and wider corner for the lower trace which further enhances magnetic field homogeneity. FIG. 9A shows a perspective view of the Design 14 modeled inductor, FIG. 9B shows a top view of the Design 14 modeled inductor, and FIG. 9C shows the Design 14HFSS near field simulation result.

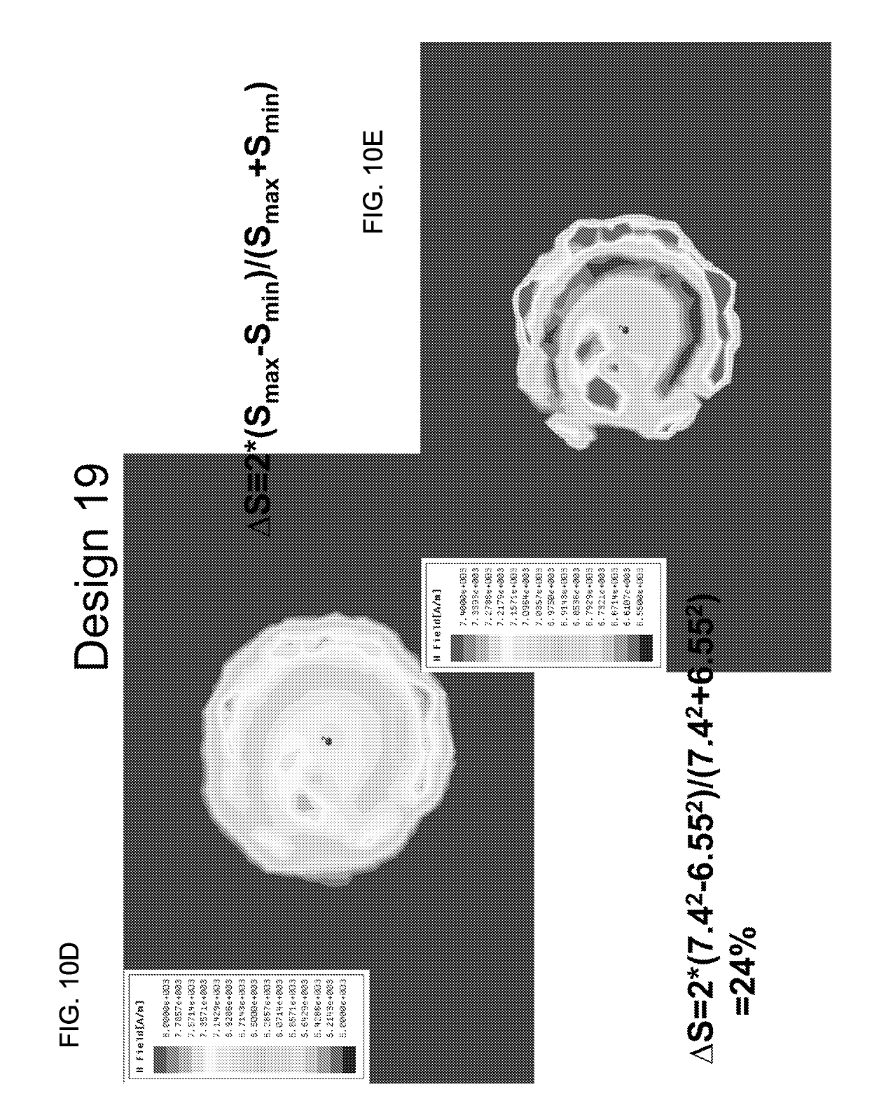

The example of FIG. 10A, FIG. 10B, FIG. 10C, FIG. 10D and FIG. 10E illustrates yet another exemplary design (our “Design 19”), having bowl-shaped inductor and a floating metal structure, an embodiment which implements a floating metal structure which further equalizes the magnetic field distribution. FIG. 10A shows a perspective view of the Design 19 modeled inductor, FIG. 10B shows a top view of the Design 19 modeled inductor, and FIG. 10C, FIG. 10D, and FIG. 10E show the Design 19 HFSS near field simulation results. FIG. 10C, FIG. 10D, and FIG. 10E demonstrate the excitation magnetic field distribution (in terms of H field) for different sensing inductor geometries, all of which have been subjected to the same excitation current. Based on the comparison, it can be seen that the homogeneity of the magnetic field has been improved through the design iterations.

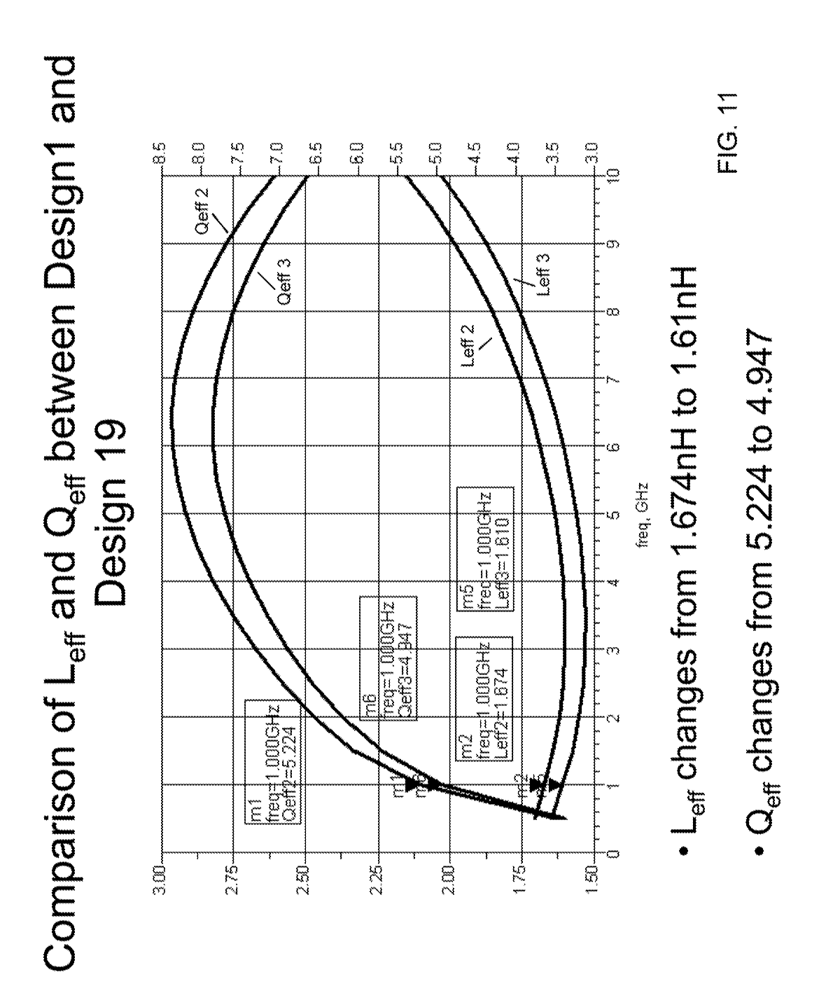

FIG. 11 shows a graph of effective inductance and effective Q plotted versus frequency for our Design 1 and our Design 19. L_{eff2} and Q_{eff2} show the effective inductance and quality factor for design 19 without the floating metal structure. L_{eff3} and Q_{eff3} show the effective inductance and quality factor for design 19 with a floating metal structure. As seen in FIG. 11, the addition of a floating metal structure can slightly degrade the effective inductance and the quality factor of the sensing inductor.

### Systems

### Sensor System Implementation

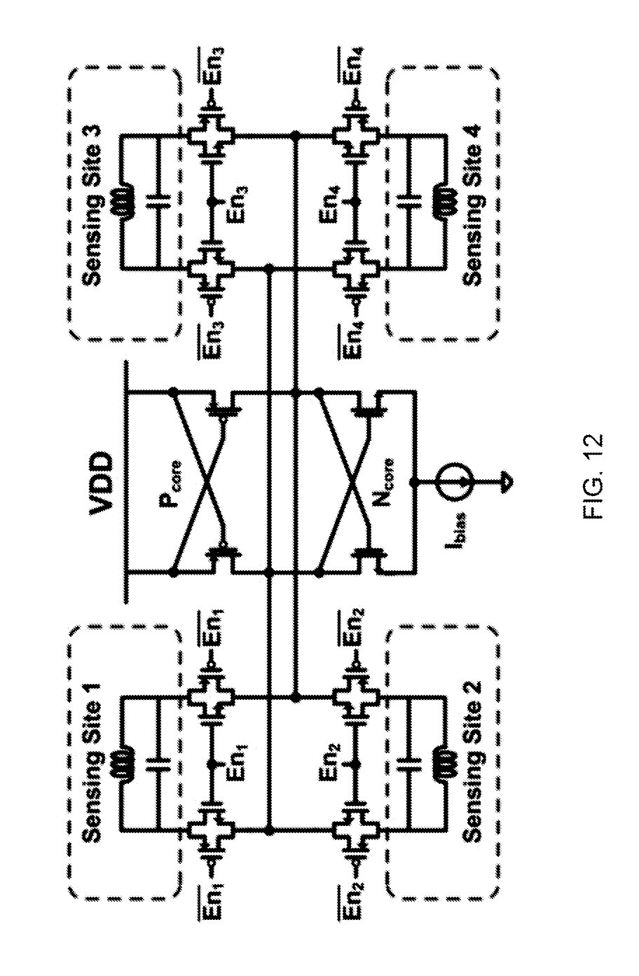

We now describe an exemplary sensor system suitable for use with the inventive sensing inductors described herein. FIG. 12 shows a schematic diagram of one exemplary quad-core sensor cell where four LC tanks are used as four sensing sites. In one implemented embodiment, the outer diameter of the sensing inductors was 110 μm.

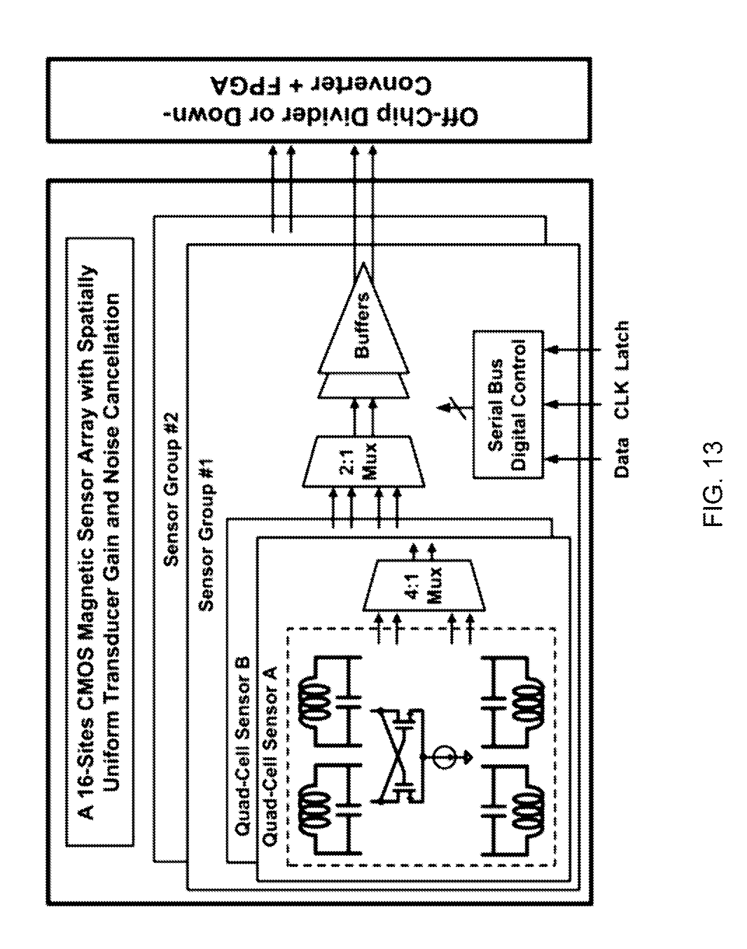

FIG. 13 shows a block diagram of one exemplary sensor system architecture suitable for use with the exemplary quad-core sensor cell. NMOS/PMOS switch pairs can be used to couple the LC tank to the complementary active core. A Differential sensing functionality can be provided by using any of the sensing sites of a multi-core sensor cell as a reference sensor. For example, in the case of a quad-core sensor cell, one site can serve as the reference sensor, while the other three sites serve as active sensors to suppress common-mode frequency-drift.

Sharing the active cores also allows for the use of a Correlated Double Counting (CDC) for noise cancellation technique. The oscillator's 1/f³ phase noise, due to active core flicker noise up-conversion, generally limits the sensor noise floor. In a CDC scheme, this noise is correlated between differential sensing measurements through active core sharing and therefore receives direct suppression for sensitivity improvement. Both the suppression of common mode drift and Correlated Double Counting have been described in more detail in the related applications listed herein above.

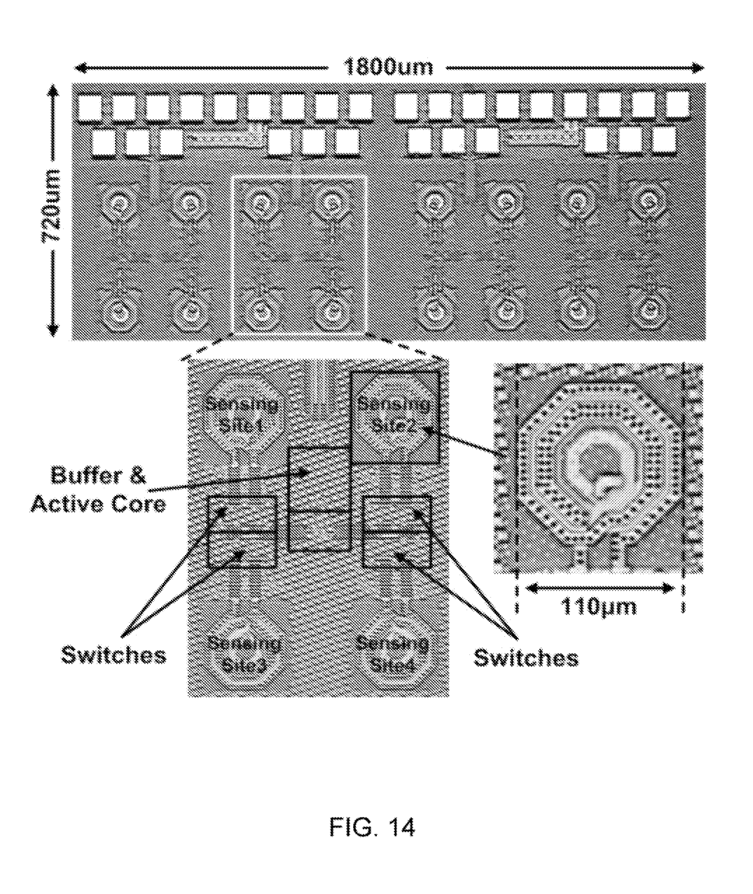

Example: FIG. 14 shows a chip micrograph of one embodiment of a sensor system implemented according to the block diagram of FIG. 13. This sensor array having 16 parallel sites was designed in a 45 nm CMOS SOI process and has a total power consumption of 73 mW. Multiplexers were used to feed the sensing oscillators' signals to the on-chip output buffers chain. The frequency results were detected by an off-chip FPGA. This architecture is completely scalable to a very-large-scaled array on the same chip. Such very-large-scaled arrays can have any desired number of sensor cells or arrays of sensor cells. In addition, with only DC supplies and digital signals as I/O (input/output), multiple chips can be easily tiled for ultra-high throughput applications, including genomic sequencing or genotyping. Results of sensor system measurements (e.g. magnetic particle counts) can be recorded (see definitions).

### Electrical Performance—Noise Cancellation

Continuing now with test results for the exemplary integrated system of FIG. 14, the sensing oscillator operated at a nominal frequency of 1.13 GHz. Its phase noise was measured with an RDL phase noise analyzer (formerly available from RDL, Inc. of Conshohocken, Pa., now Aeroflex, of Wichita, Kans.), achieving −47.2 dBc/Hz and −120.3 dBc/Hz at 1 kHz and 1 MHz offsets, respectively.

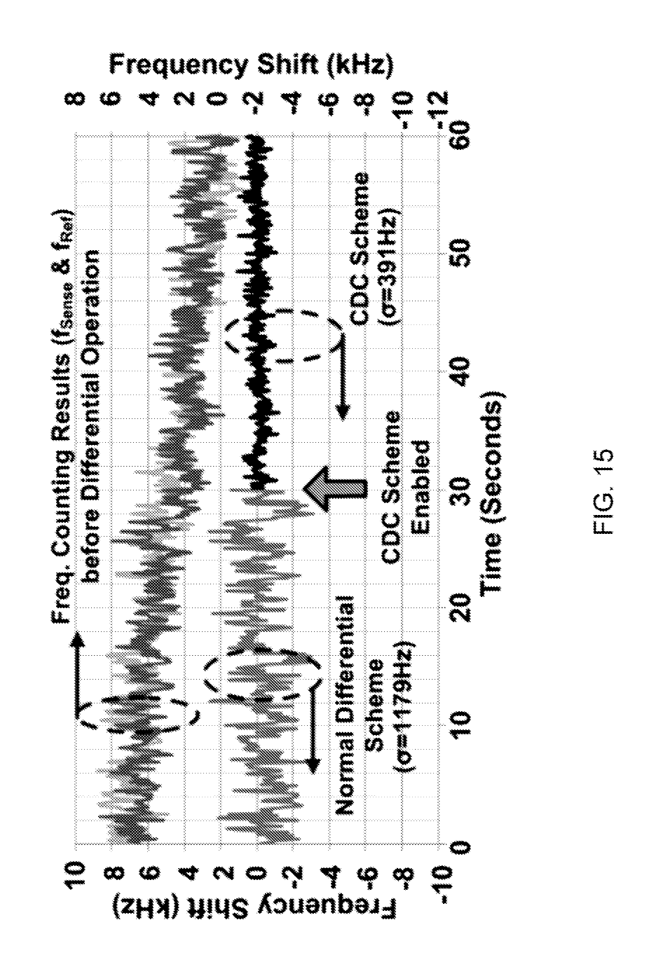

FIG. 15 shows a graph of frequency counting results (with counting duration T of 0.1 s) in the time domain for normal differential and no differential operation. The normal differential scheme suppresses the common-mode frequency-drift, while an additional noise reduction (from σ=1179 Hz to σ=391 Hz) was achieved after enabling the CDC scheme.

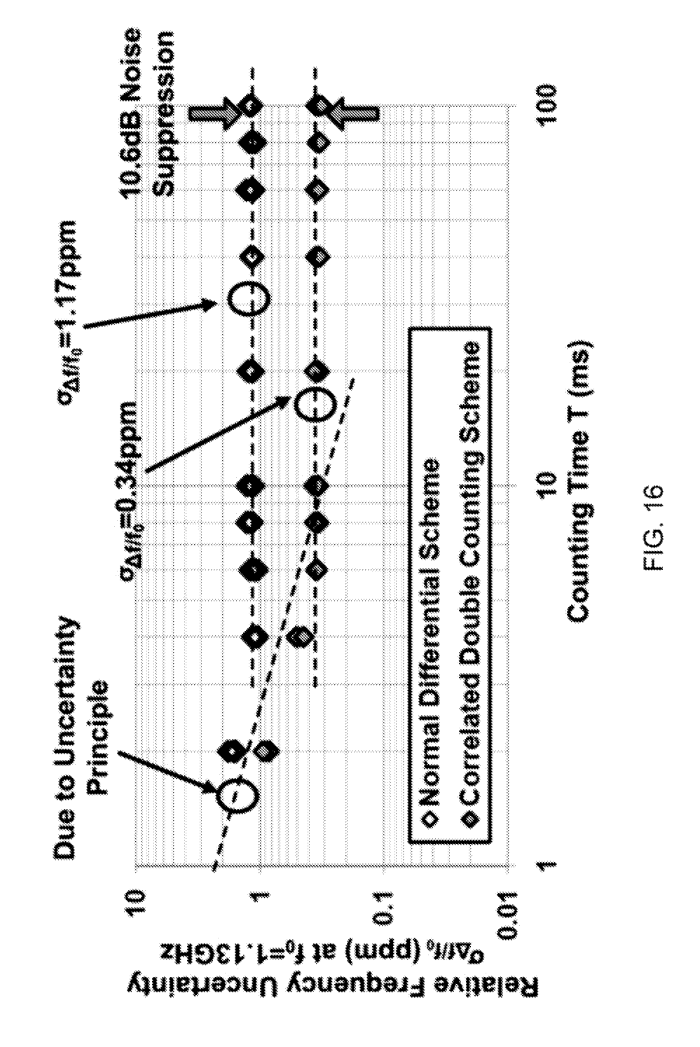

FIG. 16 shows a graph of Frequency counting standard deviation for several different counting times T. During counting, the standard deviation of frequency measurement due to sensor electrical noise (1/f3 phase noise) is plotted with respect to different counting time T. Overall, the exemplary system achieved a 10.6 dB noise suppression.

### Magnetic Sensing Performance—Uniform Transducer Gain

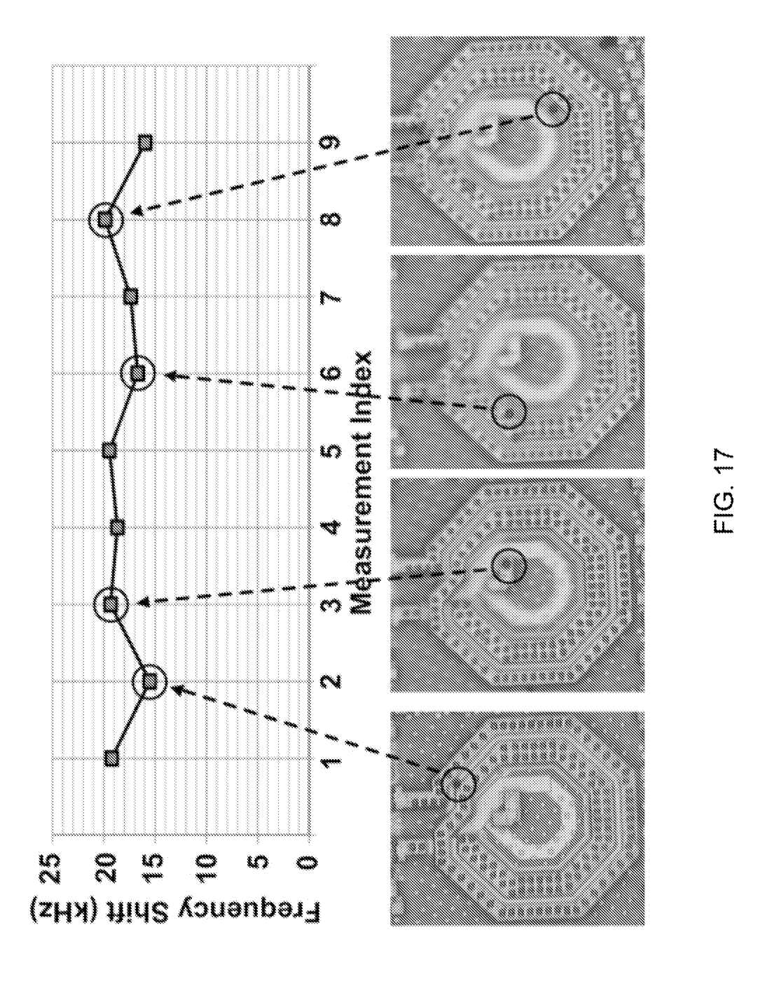

To verify the sensor gain uniformity, two sets of magnetic sensing experiments were performed. Magnetic particles, DynaBeads® M450-Epoxy (Diameter=4.5 μm), were used as the test samples in both measurements due to their ease of handling. For each measurement, one single particle was randomly placed onto the sensing surface and the sensor response and the particles' position were recorded and plotted. FIG. 17 shows a graph of four such measurements, with arrows from each of the micrographs below showing specific examples of how particular locations of the particles on the inductor sensor surface correlated to specific measured data points of the graph. Each of the four micrographs shows the location of a single randomly placed 4.5 μm particle on the sensing surface of a sensor inductor. In each micrograph, the particle is highlighted by a circle and an arrow is drawn from each circle to a corresponding data point on the graph above, indicating the measured frequency shift for a single particle in that location on the sensor surface. The consistent frequency-shift reading (average value of 18 kHz per particle) verified the uniform sensor transducer gain.

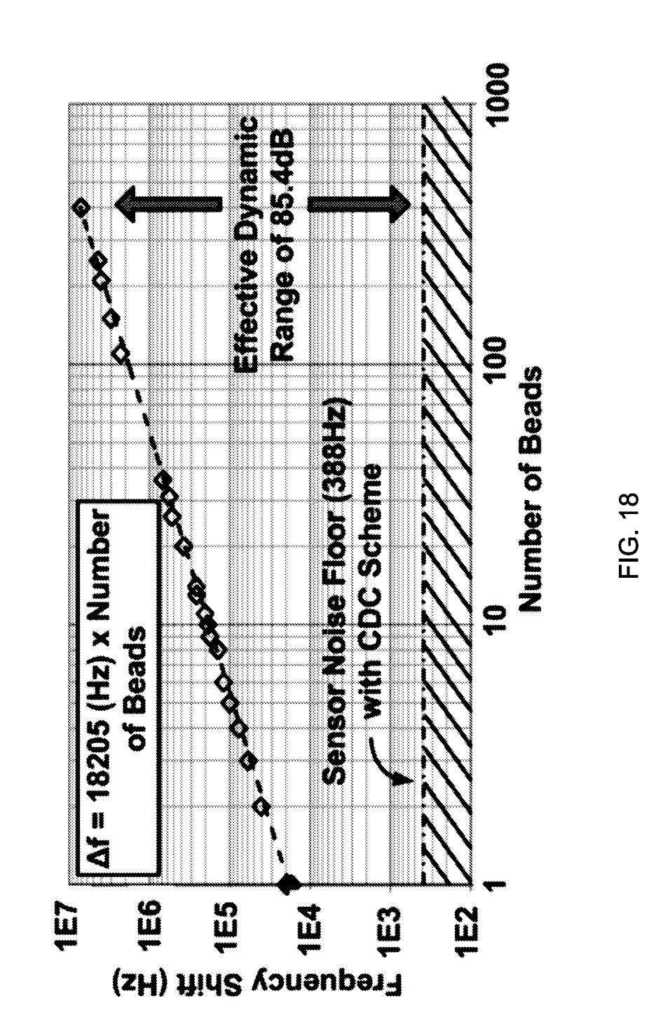

In the second experiment, different numbers of magnetic particles were deposited onto the sensor surface and their corresponding output frequency-shifts are shown in the graph of FIG. 18. The graph of FIG. 18 shows frequency shift plotted versus the number of beads present on the sensor surface. Note that with a noise floor of 388 Hz after CDC operation, a single 4.5 μm magnetic particle is still far above our sensing limit. The measured linear response (up to 409 beads) indicates an effective dynamic range of at least 85.4 dB. To the best of applicants' knowledge, this is the highest dynamic range among any CMOS biosensor modalities reported so far. It is also contemplated that such sensor systems as described herein are suitable for use with bio-samples on genomics level (DNA/RNA) and cellular level (bacteria).

A scalable ultrasensitive CMOS magnetic sensor array, modeling examples, and exemplary implemented sensors and systems have been described herein above. Our sensing inductor design method significantly improves the spatial uniformity of the transducer gain across the sensing area and directly increases the system dynamic range. An exemplary 16-cell sensor array was implemented in a 45 nm CMOS SOI process together with the CDC noise cancellation scheme. The test results verified both the spatially uniform transducer gain and the noise suppression functionality.

### Definitions

As used in the present disclosure, we define the range of electromagnetic waves from microwave to “mm-wave” to correspond generally to a frequency range of about 10 to 300 GHz. The more general term of “high frequency” includes sub mm-wave as well as mm-wave frequencies. The sensor measurement techniques described herein are particularly advantageous in adapting semiconductor processes, such as for example, digital CMOS processes, to mm-wave operation. However, it is understood that the technologies described herein can also be applied generally to any similar circuits operating at any high frequency.

The words terminal or terminals are used to define connection points between electronic function blocks as well as connection points to an integrated structure and between integrated structures on a common chip or common substrate. Therefore, it is understood that some terminals are defined by integrated structures and connecting integrated structures, while other terminals can correspond to integrated structures such as pads for connecting to off-chip structures (e.g. other integrated devices, antennas, power sources, etc.).

Recording the results from an operation or data acquisition, such as for example, recording results for a particular sensor measurement, is understood to mean and is defined herein as writing output data in a non-transitory manner to a storage element, to a machine-readable storage medium, or to a storage device. Non-transitory machine-readable storage media that can be used in the invention include electronic, magnetic and/or optical storage media, such as magnetic floppy disks, hard disks, solid state drives (SSD); a DVD drive, a CD drive that in some embodiments can employ DVD disks, any of CD-ROM disks (i.e., read-only optical storage disks), CD-R disks (i.e., write-once, read-many optical storage disks), and CD-RW disks (i.e., rewriteable optical storage disks); and electronic storage media, such as RAM, ROM, EPROM, Compact Flash cards, PCMCIA cards, ExpressCard cards or alternatively SD or SDIO memory; and the electronic components (e.g., floppy disk drive, DVD drive, CD/CD-R/CD-RW drive, or Compact Flash/PCMCIA/SD adapter) that accommodate and read from and/or write to the storage media. Unless otherwise explicitly recited, any reference herein to “record” or “recording” is understood to refer to a non-transitory record or a non-transitory recording.

As is known to those of skill in the machine-readable storage media arts, new media and formats for data storage are continually being devised, and any convenient, commercially available storage medium and corresponding read/write device that may become available in the future is likely to be appropriate for use, especially if it provides any of a greater storage capacity, a higher access speed, a smaller size, and a lower cost per bit of stored information. Well known older machine-readable media are also available for use under certain conditions, such as punched paper tape or cards, magnetic recording on tape or wire, optical or magnetic reading of printed characters (e.g., OCR and magnetically encoded symbols) and machine-readable symbols such as one and two dimensional bar codes. Recording image data for later use (e.g., writing an image to memory or to digital memory) can be performed to enable the use of the recorded information as output, as data for display to a user, or as data to be made available for later use. Such digital memory elements or chips can be standalone memory devices, or can be incorporated within a device of interest. “Writing output data” or “writing an image to memory” is defined herein as including writing transformed data to registers within a microcomputer.

“Microcomputer” is defined herein as synonymous with microprocessor, microcontroller, and digital signal processor (“DSP”). It is understood that memory used by the microcomputer, including for example instructions for data processing coded as “firmware” can reside in memory physically inside of a microcomputer chip or in memory external to the microcomputer or in a combination of internal and external memory. Similarly, analog signals can be digitized by a standalone analog to digital converter (“ADC”) or one or more ADCs or multiplexed ADC channels can reside within a microcomputer package. It is also understood that field programmable array (“FPGA”) chips or application specific integrated circuits (“ASIC”) chips can perform microcomputer functions, either in hardware logic, software emulation of a microcomputer, or by a combination of the two. Apparatus having any of the inventive features described herein can operate entirely on one microcomputer or can include more than one microcomputer.

General purpose programmable computers useful for controlling instrumentation, recording signals and analyzing signals or data according to the present description can be any of a personal computer (PC), a microprocessor based computer, a portable computer, or other type of processing device. The general purpose programmable computer typically comprises a central processing unit, a storage or memory unit that can record and read information and programs using machine-readable storage media, a communication terminal such as a wired communication device or a wireless communication device, an output device such as a display terminal, and an input device such as a keyboard. The display terminal can be a touch screen display, in which case it can function as both a display device and an input device. Different and/or additional input devices can be present such as a pointing device, such as a mouse or a joystick, and different or additional output devices can be present such as an enunciator, for example a speaker, a second display, or a printer. The computer can run any one of a variety of operating systems, such as for example, any one of several versions of Windows, or of MacOS, or of UNIX, or of Linux. Computational results obtained in the operation of the general purpose computer can be stored for later use, and/or can be displayed to a user. At the very least, each microprocessor-based general purpose computer has registers that store the results of each computational step within the microprocessor, which results are then commonly stored in cache memory for later use.

Many functions of electrical and electronic apparatus can be implemented in hardware (for example, hard-wired logic), in software (for example, logic encoded in a program operating on a general purpose processor), and in firmware (for example, logic encoded in a non-volatile memory that is invoked for operation on a processor as required). The present invention contemplates the substitution of one implementation of hardware, firmware and software for another implementation of the equivalent functionality using a different one of hardware, firmware and software. To the extent that an implementation can be represented mathematically by a transfer function, that is, a specified response is generated at an output terminal for a specific excitation applied to an input terminal of a “black box” exhibiting the transfer function, any implementation of the transfer function, including any combination of hardware, firmware and software implementations of portions or segments of the transfer function, is contemplated herein, so long as at least some of the implementation is performed in hardware.

### Theoretical Discussion

The physical process, which relates the presence of magnetic particles with frequency down-shift can be further modeled as follows. Assume a magnetic particle with effective susceptibility χ_{eff} and a volume Vₚ is placed close to the on-chip sensing inductor. When a current I conducts through the coil, the local polarization magnetic field is \vec{H}. Assuming the presence of the magnetic particle will not alter this H\vec{}, the total magnetic energy therefore increases by ΔEₘ after placing the particle,

$$\begin{matrix}Δ {E}_{m} = ( {E}_{m ′} - {E}_{m} ) \\ = \frac{1}{2} \int \int \int {H}^{->} \cdot {{B}^{′}}^{->} d v - \frac{1}{2} \int \int \int {H}^{->} \cdot {B}^{->} d v \\ = \frac{{μ}_{0}}{2} \int \int {\int }_{{V}_{p}} [ {‖ {H}^{->} ‖}^{2} ( 1 + {χ}_{eff} ) - {‖ {H}^{->} ‖}^{2} ] d v \\ = \frac{{χ}_{eff}}{2 {μ}_{0}} \int \int {\int }_{{V}_{p}} {‖ {B}^{->} ‖}^{2} d v \\ \approx \frac{{χ}_{eff}}{2 {μ}_{0}} {‖ {B}^{->} ‖}^{2} {V}_{p}\end{matrix} \qquad ( 1 )$$

where \vec{B′} and \vec{B} are the local magnetic flux density with and without the magnetic particle. The approximation holds when the particle is small enough so that the polarization field is homogenous across its volume.

The sensor transducer gain can be defined as the relative frequency-shift (due to the inductance change) per particle as,

$$\begin{matrix}Transducer Gain = {( \frac{Δ f}{{f}_{0}} )}_{per particle} \\ = - \frac{Δ L}{2 {L}_{0}} \\ = - \frac{1}{2} \cdot \frac{2 Δ {E}_{m} / {I}^{2}}{{L}_{0}} \\ = - \frac{1}{2} \cdot \frac{2 \frac{{χ}_{eff}}{2 {μ}_{0}} {‖ {B}^{->} ‖}^{2} {V}_{p} / {I}^{2}}{{L}_{0}} \\ = - \frac{1}{2} \cdot \frac{{χ}_{eff} {V}_{p}}{{μ}_{0} {L}_{0}} \cdot \frac{{‖ {B}^{->} ‖}^{2}}{{I}^{2}}\end{matrix} \qquad ( 2 )$$

Equation (2) shows that the sensor transducer gain can be location-dependent on the sensor surface and is proportional to the field quantity ∥\vec{B}∥²/I².

Although the theoretical description given herein is thought to be correct, the operation of the devices described and claimed herein does not depend upon the accuracy or validity of the theoretical description. That is, later theoretical developments that may explain the observed results on a basis different from the theory presented herein will not detract from the inventions described herein.

Any patent, patent application, or publication identified in the specification is hereby incorporated by reference herein in its entirety. Any material, or portion thereof, that is said to be incorporated by reference herein, but which conflicts with existing definitions, statements, or other disclosure material explicitly set forth herein is only incorporated to the extent that no conflict arises between that incorporated material and the present disclosure material. In the event of a conflict, the conflict is to be resolved in favor of the present disclosure as the preferred disclosure.

While the present invention has been particularly shown and described with reference to the preferred mode as illustrated in the drawing, it will be understood by one skilled in the art that various changes in detail may be affected therein without departing from the spirit and scope of the invention as defined by the claims.

What is claimed is:

1. An integrated inductor comprising:
a plurality of coils, each of said plurality of coils electromagnetically coupled together to form an inductor between a first inductor terminal and a second inductor terminal; and
at least one of said plurality of coils disposed in a layer on an integrated structure and at least another of one of said plurality of coils disposed in a layer of said integrated structure, one of said plurality of coils spaced with respect to another of said plurality of coils to cause a substantially uniform magnetic field strength across a surface of said integrated inductor.

2. The integrated inductor of claim 1, wherein at least one of said plurality of stacked coils is disposed in first layer of said integrated structure and at least another one of said plurality of coils is disposed in a second layer of said integrated structure.

3. The integrated inductor of claim 1, wherein at least two of said plurality of stacked coils have different diameters and said plurality of stacked coils creates a geometric bowl shaped inductor.

4. The integrated inductor of claim 1, further comprising at least one floating metal structure.

5. The integrated inductor of claim 1, further comprising an interconnecting trace electrically coupled between said at least one of said plurality of coils at least another of one of said plurality of coils, said interconnecting trace configured to provide a gradual vertical transition to adjust the current distribution within said integrated inductor magnetic sensor device.

6. The integrated inductor of claim 1, further comprising an inner widened turn.

7. An integrated magnetic particle sensor system comprising:
at least one integrated magnetic particle sensor inductor having a feature of a selected one of: a bowl-shaped inductor, a floating metal structure, and a section of a trace having a different width than another section, said integrated magnetic particle sensor inductor configured to provide a substantially homogenous near-field magnetic field at a sensing surface, said integrated magnetic particle sensor inductor electrically coupled to an integrated capacitor and configured as an oscillator LC sensing core, said LC sensing core configured such that a frequency of said oscillator LC sensing core is indicative of the presence of one or more magnetic particles.

8. The integrated magnetic particle sensor system of claim 7, wherein said integrated magnetic particle sensor is configured to detect the presence of one or more magnetic particles.

9. The integrated magnetic particle sensor system of claim 8, wherein said single magnetic particle is detectable at any location on of said sensing surface.

10. The integrated magnetic particle sensor system of claim 7, wherein at least one of said one or more magnetic particles is affixed to a target molecule.

11. The integrated magnetic particle sensor system of claim 7, wherein said integrated magnetic particle sensor is configured to provide a linear sensor response with respect to a number of magnetic particles.

12. The integrated magnetic particle sensor system of claim 7, further comprising one or more additional LC sensing cores to form an array of LC sensing cores, each of said LC sensing cores is selected by a multiplexer.

13. The integrated magnetic particle sensor system of claim 12, wherein said integrated magnetic particle sensor system is configured to use a Correlated Double Counting (CDC) for noise cancellation.

14. The integrated magnetic particle sensor system of claim 12, wherein at least one of said LC sensing core and said n additional LC sensing cores is configured as a reference cell, and the remaining LC sensing cores are configured as measurement cells.

15. The integrated magnetic particle sensor system of claim 12, further comprising m arrays of n LC sensing cores and wherein each of said m arrays is selected by a multiplexer.

16. The integrated magnetic particle sensor system of claim 7, wherein said integrated magnetic particle sensor system comprises a bio-sensing system.

17. The integrated magnetic particle sensor system of claim 7, wherein said bio-sensing system is configured for use with a selected one of, genomics level (DNA/RNA) bio-sample and cellular level (bacteria) bio-sample.

18. An integrated inductor comprising:
a plurality of coils, each of said plurality of coils electromagnetically coupled together to form an inductor between a first inductor terminal and a second inductor terminal; and
at least one of said plurality of coils disposed in a layer on an integrated structure and at least another of one of said plurality of coils disposed in a layer of said integrated structure, at least a portion of one coil of said plurality of coils having a section having a different width than another section and configured to cause a substantially uniform magnetic field strength across a surface of said integrated inductor.

19. An integrated inductor comprising:
a plurality of coils, each of said plurality of coils electrically coupled together to form an inductor between a first inductor terminal and a second inductor terminal;
at least one of said plurality of coils disposed in a layer on an integrated structure and at least another of one of said plurality of coils disposed in a layer of said integrated structure; and
at least one gradual transition section disposed between at least two coils of said plurality of coils configured to cause a substantially uniform magnetic field strength across a surface of said integrated inductor.

20. An integrated inductor comprising:
a plurality of coils, each of said plurality of coils electromagnetically coupled together to form an inductor between a first inductor terminal and a second inductor terminal;
at least one of said plurality of coils disposed in a layer on an integrated structure and at least another of one of said plurality of coils disposed in a layer of said integrated structure; and
at least one floating metal structure disposed on or near a said layer has a substantially optimized geometry configured to cause a substantially uniform magnetic field strength across a surface of said integrated inductor.
